(19) United States
(12) Patent Application Publication
(10) Pub. No.: US 2024/0226641 A1
(43) Pub. Date: Jul. 11, 2024

(54) DUMBBELL

(71) Applicant: Michael Rudan, Niagara Falls (CA)

(72) Inventor: Michael Rudan, Niagara Falls (CA)

(21) Appl. No.: 18/614,282

(22) Filed: Mar. 22, 2024

Related U.S. Application Data
(63) Continuation-in-part of application No. 17/162,062, filed on Jan. 29, 2021, now Pat. No. 11,641,737.
(60) Provisional application No. 62/968,012, filed on Jan. 30, 2020.
(60) Provisional application No. 63/453,895, filed on Mar. 22, 2023.

(51) Int. Cl. A63B 21/072

(52) U.S. Cl. CPC A63B 21/0726

(57) ABSTRACT

An improved dumbbell free weight is discussed, which includes one or more base weights, the dumbbell further having a pair of second, upper weights positioned above where the upper weights are suspended by second support members extending from a handle attached to the one or more base weights via first support members.

### CROSS-REFERENCE TO RELATED APPLICATIONS

This application is a continuation-in-part of U.S. patent application Ser. No. 17/162,092 filed Jan. 29, 2021, which claims priority of U.S. provisional patent application Ser. No. 62/968,012 filed Jan. 30, 2020, and further claims priority of U.S. provisional patent application Ser. No. 63/453,895 filed Mar. 22, 2023, all of which are incorporated by reference into this application in their entirety.

### TECHNICAL FIELD

The present disclosure is related to the field of fitness equipment, in particular, free weights in the form of improved dumbbell weights that can be used in training in sports such as boxing.

### BACKGROUND

Kettle bells are known forms of free weights, typically, in the form of a weight formed of metal, such as steel or iron, with a single loop-style handle attached to the weight. One problem with using kettle bells is that by virtue of their shape is that it can be difficult to hold the weight in a fixed position in a person's hand when the weight is lifted up an angle, such as in a side or front lateral raise exercise, where the weight handle will twist in the person's hand as the weight will rotate towards the ground due to gravity.

It is, therefore, desirable to provide an improved dumbbell weight that overcomes this problem.

### SUMMARY

An improved dumbbell is provided. In some embodiments, the improved dumbbell can comprise a base weight with first support members extending substantially upwards therefrom with a substantially horizontal handle extending between upper ends of the first support members, wherein the improved dumbbell comprises a pair of upper weights supported by two sets of second support members extending substantially upwards from the upper ends of the first support members, thereby forming a “dumbbell-like” structure except that the handle is substantially orthogonal to an axis extending between the upper weight and the lower weight.

In some embodiments, the improved dumbbell can comprise a handle with a plurality of support members extending from one end of the handle, wherein each support member comprises a weight extending therefrom. In some embodiments, the combination of each weight and corresponding support members can comprise a curved or arc configuration to provide a space for a person place their hand between the weights and grasp the handle.

Broadly stated, in some embodiments, a dumbbell can be provided, comprising: a substantially straight handle segment disposed along a longitudinal axis between a pair of end faces; and a plurality of curved weight segments disposed along an arc path between the paid of end faces thereby enclosing the handle segment.

Broadly stated, in some embodiments, the handle segment can be rotatably attached to the dumbbell.

Broadly stated, in some embodiments, the handle segment can comprise an opening extending therethrough between the pair of end faces.

Broadly stated, in some embodiments, a strap can be disposed through the opening, the strap further comprising a ring for attachment to weight resistance exercise equipment.

Broadly stated, in some embodiments, the dumbbell can further comprise a barbell having first and second ends, the first end disposed in the opening of the dumbbell, the second end disposed in the opening of another of the dumbbell.

Broadly stated, in some embodiments, the dumbbell can further comprise an attachment mechanism disposed on one or both of the end faces, the attachment mechanism for attaching to weight resistance exercise equipment.

Broadly stated, in some embodiments, the dumbbell can further comprise an attachment mechanism disposed on one or more of the curved weight segments, the attachment mechanism for attaching to weight resistance exercise equipment.

Broadly stated, in some embodiments, the attachment mechanism can comprise a loop or a ring.

Broadly stated, in some embodiments, an improved dumbbell can be provided, comprising: a handle; a plurality of support members extending from one end of the handle; and a weight disposed on each of the plurality of support members.

Broadly stated, in some embodiments, the combination of each of the weights and their corresponding support members can comprise a curved or arc configuration.

Broadly stated, in some embodiments, the handle can comprise a grip disposed at least partially thereon or therearound.

Broadly stated, in some embodiments, the grip can comprise an elastomeric material.

Broadly stated, in some embodiments, the handle can comprise an opening disposed on one thereof.

Broadly stated, in some embodiments, the improved dumbbell can further comprise a weight stand having at least one peg extending therefrom, wherein the at least one peg is configured to fit within the opening so as to place or store the improved dumbbell on the at least one peg.

Broadly stated, in some embodiments, an improved dumbbell can be provided, comprising: a first weight; at least one first support member extending substantially from the first weight; a substantially horizontal handle extending from a first end of the at least one first support member; a plurality of sets of at least one second support member extending from the first end of the at least one first support member; and a second weight disposed on furthermost ends of each of the at least one second support member.

Broadly stated, in some embodiments, the first weight can comprise a substantially flat bottom surface thereby the dumbbell is configured to stand unsupported without tipping over.

Broadly stated, in some embodiments, the at least one first support member can be substantially vertical extending upwardly from the first weight.

Broadly stated, in some embodiments, the at least one second support member can be rotated by an angle phi relative to the first support members.

Broadly stated, in some embodiments, the angle phi can range from 90° to 160°.

Broadly stated, in some embodiment, an improved dumbbell can be provided, comprising: a pair of base weights; two sets of first support members, wherein each of the pair of base weights comprises one of the sets of first support members extending substantially upwards therefrom; a substantially horizontal handle extending between upper ends of the first support members; two sets of second support members extending upwards from the upper ends of the first support members; and an upper weight disposed on uppermost ends of each of the two sets of second support members.

Broadly stated, in some embodiments, each of the pair of base weights can comprise a substantially flat bottom surface thereby the dumbbell is configured to stand unsupported without tipping over.

Broadly stated, in some embodiments, the two sets of first support members can be separated by an angle alpha.

Broadly stated, in some embodiments, the angle alpha can range from 45° to 135°.

Broadly stated, in some embodiments, the second support members can be rotated by an angle phi relative to the first support members.

Broadly stated, in some embodiments, the angle phi can range from 45° to 135°.

Broadly stated, in some embodiments, the upper or second weights can comprise less weight or mass than that of the base or first weight or weights.

Broadly stated, in some embodiments, the weight or mass of the upper or second weights can range from 0.1 to 1.0 of that of the base or first weight or weights.

Broadly stated, in some embodiments, the handle can comprise a proprioceptive wrap disposed at least partially therearound.

### BRIEF DESCRIPTION OF THE DRAWINGS

FIG. 1 is a block diagram depicting one embodiment of an improved dumbbell.

FIG. 2 is a photograph depicting a front elevation view of the improved dumbbell of FIG. 1.

FIG. 3 is a photograph depicting a perspective view of the improved dumbbell of FIG. 1.

FIG. 4 is a block diagram depicting a second embodiment of an improved dumbbell.

FIG. 5A is a front perspective view depicting a third embodiment of an improved dumbbell.

FIG. 5B is rear perspective view depicting the improved dumbbell of FIG. 5A.

FIG. 6A is a front perspective view depicting a fourth embodiment of an improved dumbbell.

FIG. 6B is rear perspective view depicting the improved dumbbell of FIG. 6A.

FIG. 7 is a perspective view depicting the improved dumbbell of FIG. 6A being held in an exercise position.

FIG. 8 is a perspective view depicting the improved dumbbell of FIG. 5A or 6A being mounted on a weight stand.

FIG. 9 is an end elevation view depicting one embodiment of a dumbbell weight.

FIG. 10 is a side elevation view depicting the dumbbell weight of FIG. 9.

FIG. 11 is a perspective view depicting the dumbbell weight of FIG. 9.

FIG. 12 is a perspective view depicting the dumbbell weight of FIG. 9 having a strap disposed through a handle opening thereof.

FIG. 13 is a side elevation view depicting the dumbbell weight of FIG. 12.

FIG. 14 is a perspective view depicting one embodiment of a barbell having the dumbbell weight of FIG. 11 as weights to the barbell.

FIG. 15 is a left perspective view depicting the dumbbell weight of FIG. 12 without the strap.

FIG. 16 is an end elevation view depicting the dumbbell weight of FIG. 15.

FIG. 17 is a right perspective view depicting the dumbbell weight of FIG. 15.

FIG. 18 is a front perspective view depicting a second embodiment of the dumbbell weight of FIG. 15 with attachment rings on end surfaces thereof.

FIG. 19 is a perspective view depicting a person exercising with the dumbbell of FIG. 18.

FIG. 20 is a top plan view depicting one embodiment of straps for use with the dumbbell of FIG. 18.

FIG. 21 is a perspective view depicting a person using the dumbbell of FIG. 18 and the straps of FIG. 20 as a handle on an exercise machine.

FIG. 22 is a front perspective view depicting another embodiment of the dumbbell of FIG. 18 with attachment rings on the weight segments thereof.

FIG. 23 is perspective view depicting one embodiment of a cable exercise machine for use with the dumbbell of FIGS. 18 and 22.

FIG. 24 is a perspective view depicting one embodiment of a cage for use with the dumbbell of FIGS. 18 and 22.

### DETAILED DESCRIPTION OF EMBODIMENTS:

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment can also be included in other embodiments but is not necessarily included. Thus, the present technology can include a variety of combinations and/or integrations of the embodiments described herein.

The presently disclosed subject matter is illustrated by specific but non-limiting examples throughout this description. The examples may include compilations of data that are representative of data gathered at various times during the course of development and experimentation related to the present invention(s). Each example is provided by way of explanation of the present disclosure and is not a limitation thereon. In fact, it will be apparent to those skilled in the art that various modifications and variations can be made to the teachings of the present disclosure without departing from the scope of the disclosure. For instance, features illustrated or described as part of one embodiment can be used with another embodiment to yield a still further embodiment.

All references to singular characteristics or limitations of the present disclosure shall include the corresponding plural characteristic(s) or limitation(s) and vice versa, unless otherwise specified or clearly implied to the contrary by the context in which the reference is made.

All combinations of method or process steps as used herein can be performed in any order, unless otherwise specified or clearly implied to the contrary by the context in which the referenced combination is made.

While the following terms used herein are believed to be well understood by one of ordinary skill in the art, definitions are set forth to facilitate explanation of the presently disclosed subject matter.

Unless defined otherwise, all technical and scientific terms used herein have the same meaning as commonly understood by one of ordinary skill in the art to which the presently disclosed subject matter belongs. Although any methods, devices, and materials similar or equivalent to those described herein can be used in the practice or testing of the presently disclosed subject matter, representative methods, devices, and materials are now described.

Following long-standing patent law convention, the terms “a”, “an”, and “the” refer to “one or more” when used in this application, including the claims.

Unless otherwise indicated, all numbers expressing quantities, properties, and so forth used in the specification and claims are to be understood as being modified in all instances by the term “about”. Accordingly, unless indicated to the contrary, the numerical parameters set forth in this specification and claims are approximations that can vary depending upon the desired properties sought to be obtained by the presently disclosed subject matter.

As used herein, the term “about”, when referring to a value or to an amount of mass, weight, time, volume, concentration or percentage is meant to encompass variations of in some embodiments +/−50%, in some embodiments +/−40%, in some embodiments +/−30%, in some embodiments +/−20%, in some embodiments +/−10%, in some embodiments +/−5%, in some embodiments +/−1%, in some embodiments +/−0.5%, and in some embodiments +/−0.1% from the specified amount, as such variations are appropriate to perform the disclosed method.

Alternatively, the terms “about” or “approximately” can mean within an acceptable error range for the particular value as determined by one of ordinary skill in the art, which will depend in part on how the value is measured or determined, i.e., the limitations of the measurement system. For example, “about” can mean within 3, or more than 3, standard deviations, per the practice in the art. Alternatively, “about” can mean a range of up to 20%, preferably up to 10%, more preferably up to 5%, and more preferably still up to 1% of a given value. Alternatively, particularly with respect to biological systems or processes, the term can mean within an order of magnitude, preferably within 5-fold, and more preferably within 2-fold, of a value. Unless otherwise indicated, all numbers expressing quantities, properties, and so forth used in the specification and claims are to be understood as being modified in all instances by the term “about”. And so, the numerical parameters set forth in this specification and claims are approximations that can vary depending upon the desired properties sought to be obtained by the presently disclosed subject matter.

As used herein, ranges can be expressed as from “about” one particular value, and/or to “about” another particular value. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

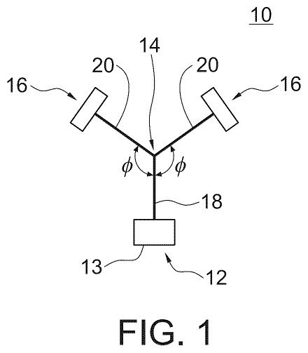

Referring to FIGS. 1 to 3, one embodiment of improved dumbbell 10 is illustrated. In some embodiments, improved dumbbell 10 can comprise of first or base weight 12 having bottom surface 13 that can be configured for resting on a flat horizontal surface such as the floor. Improved dumbbell 10 can further comprise a pair of second or upper weights 16 disposed above first or base weight 12, wherein each second or upper weight 16 is supported by the combination of a plurality of sets of at least one second support member 20, handle 14 and at least one first support member 18 operatively connecting second or upper weights 16 to first or base weight 12. In the illustrated embodiment, dumbbell 10 comprises two sets of the at least one second support member 20.

In some embodiments, handle 14 can be substantially horizontal and disposed vertically between second or upper weights 16 and first or base weight 12. In some embodiments, first support members 18 can extend from ends 15 of handle 14 to first or base weight 12, and a set of second support members 20 can extend from ends 15 to each second or upper weight 16.

In some embodiments, as shown in FIG. 1, each second support member 20 can be disposed at a first angle relative to first support member 18 as depicted by angle “φ” (“phi”). In some embodiments, angle phi can range from 90° to 160°. In the illustrated embodiment, angle phi is approximately 120°.

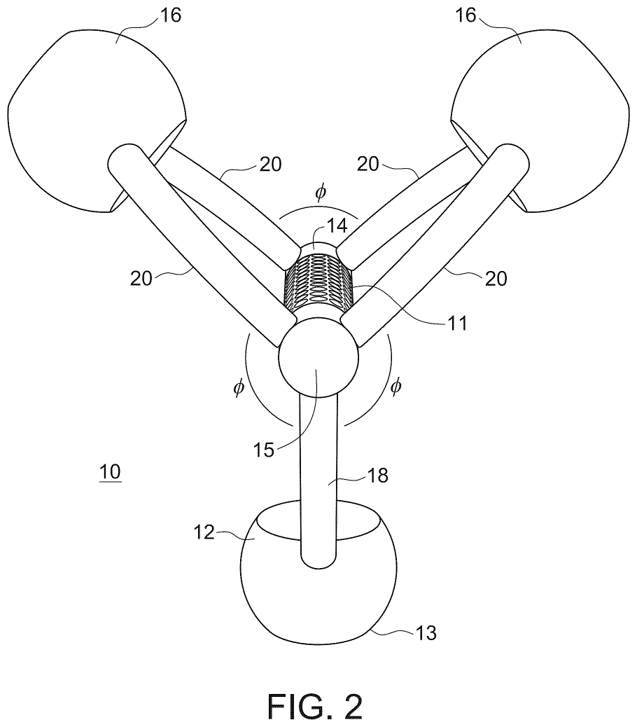

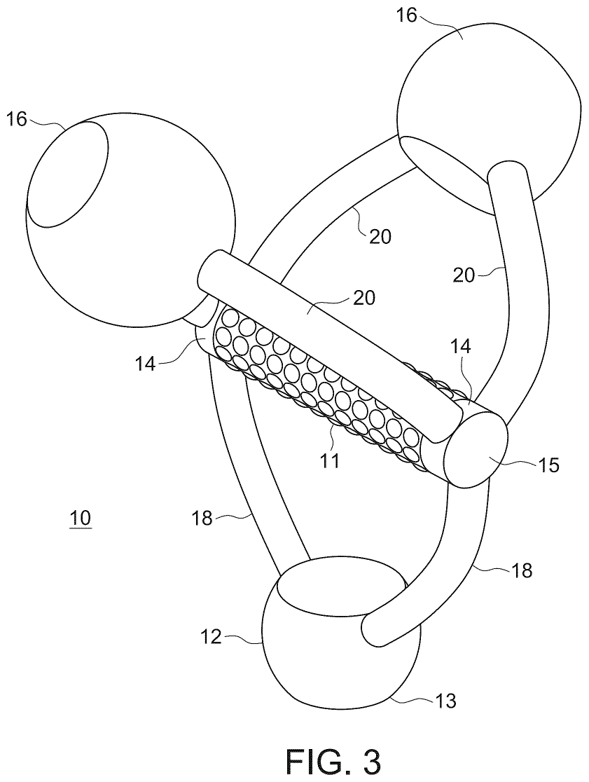

In some embodiments, each second or upper weight 16 can comprise less weight or mass than that of first or base weight 12. In some embodiments, each second or upper weight 16 can range from approximately 0.1 or 10% to approximately 1.0 or 100% of the weight or mass of first or base weight 12. In the illustrated embodiment of improved dumbbell as shown in FIGS. 2 and 3, first or base weight 12 is approximately 10 pounds in weight and each second or upper weight 16 is approximately 5 pounds in weight.

By configuring improved dumbbell 10 with angle phi as applied to support members 18 and 20, respectively, each second or upper weight 16 can be positioned substantially above first or base weight 12 such that improved dumbbell 10 is stable when bottom surface 13 is placed on a floor. In addition, the space between the two second or upper weights 16 can provide clearance for a person's hand to easily grasp handle 14 between upper weights 16. By configuring improved dumbbell 10 in this manner, traditional free weight conventional dumbbell exercises can be performed with little or no twisting of handle 14 in the person's hand. In addition, the placement of upper weight 16 above the hand, in combination of the placement of base weight 12 below the hand, can result in additional muscles being worked when performing traditional free weight exercises as the improved dumbbell is being lifted and moved during these exercises.

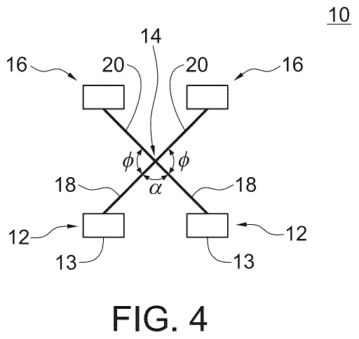

Referring to FIG. 4, a second embodiment of improved dumbbell 10 is shown. In this embodiment, improved dumbbell 10 can comprise a pair of base weights 12 each having bottom surface 13 that can be configured for resting on a flat horizontal surface such as the floor. Improved dumbbell 10 can further comprise a pair of upper weights 16 disposed above base weight 12, wherein each upper weight 16 is supported by the combination of second support members 20, handle 14 and first support members 18 operatively connecting upper weights 16 to base weight 12.

As with the embodiment shown in FIG. 1, handle 14 in the embodiment shown in FIG. 4 can be substantially horizontal and disposed vertically between upper weights 16 and base weights 12. In some embodiments, a set of first support members 18 can extend from ends 15 of handle 14 to each base weight 12, and a set of second support members 20 can extend from ends 15 to each upper weight 16.

In some embodiments, as shown in FIG. 4, each second support member 20 can be disposed at a first angle relative to the nearest first support member 18 as depicted by angle “φ” (“phi”). In some embodiments, angle phi can range from 45° to 135°. In the illustrated embodiment, angle phi is approximately 90°.

In some embodiments, as shown in FIG. 4, each set of first support members 18 can be disposed at a second angle relative to the other set of first support members 18 as depicted by angle “α” (“alpha”). In some embodiments, angle alpha can range from 45° to 135°. In the illustrated embodiments, angle alpha is approximately 45°.

In some embodiments, each of the embodiments of dumbbell 10 described herein can comprise wrap 11 disposed at least partially around handle 14 as shown in FIGS. 2 and 3, and as described in applicant's U.S. patent application Ser. No. 16/319,168 filed on Jan. 18, 2019, which is incorporated by reference into this application in its entirety. The wrap can comprise a compressible proprioceptive material as described in applicant's U.S. patent application Ser. No. 16/319,168. The wrap can provide a proprioceptive response to a person using improved dumbbell 10 in an exercise activity.

In some embodiments, one or both of first support members 18 and second support members 20 can each comprise a curvilinear configuration or path between ends 15 relative to handle 14 that can be substantially linearly straight in configuration. In some embodiments, the curvilinear configuration or path of support members 18 and 20 can provide additional space therebetween and handle 14 for a person to place their hand therearound while keeping the overall size of dumbbell 10 smaller than conventional dumbbells.

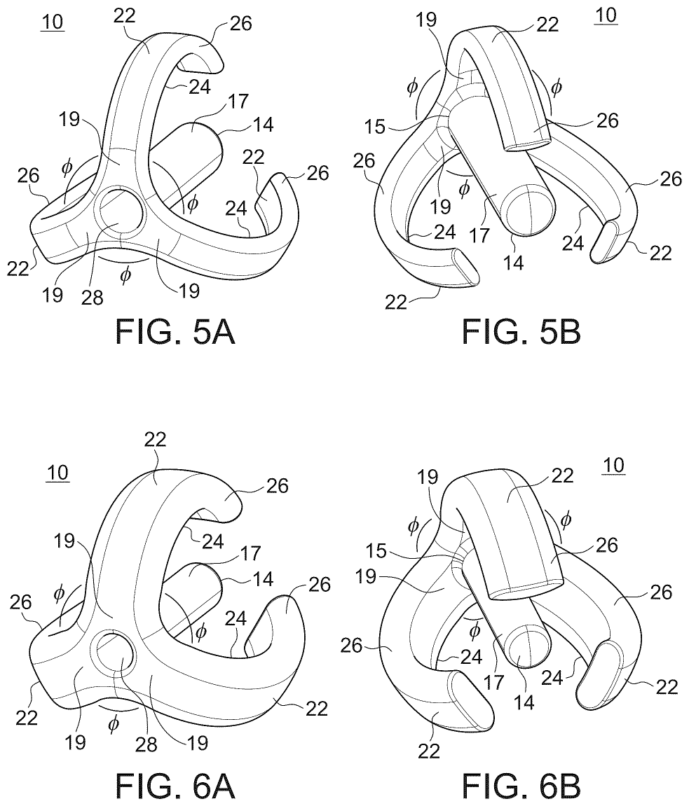

Referring to FIGS. 5A and 5B, a third embodiment of improved dumbbell 10 is shown. In this embodiment, improved dumbbell 10 can comprise a plurality of weights 22 extending from braces 19 operatively coupled to end 15 of handle 14. In some embodiments, handle 14 can comprise grip 17 disposed at least partially thereon or therearound to provide improved grip to dumbbell 10 as well known to those skilled in the art. In some embodiments, grip 17 can be comprised of neoprene, rubber or other elastomeric material well known to those skilled in the art to provide enhanced grip to dumbbell 10. In other embodiments, grip 17 can comprise knurling on handle 14 to provide enhanced grip thereto. In some embodiments, handle 14 can further comprise wrap 11 (as shown in FIGS. 2 and 3) disposed at least partially therearound. In the illustrated embodiment, dumbbell 10 can comprise three weights 22 wherein each weight 22 is disposed substantially equidistant apart from an adjacent weight 22 wherein each weight 22 is disposed rotate by angle phi apart from its adjacent weights 22. In the illustrated embodiment, angle phi can be substantially 120°. In some embodiments, one or more weights 22 can be curved in configuration to form arc 24 as shown in FIGS. 5A and 5B. In some embodiments, arc 24 can provide additional space between weights 22 and handle 14 for a person to place their hand therearound while keeping the overall size of dumbbell 10 smaller than conventional dumbbells. In some embodiments, this embodiment of dumbbell can be comprised of metal, non-metal material with metal disposed therein or other suitable materials well known to those skilled in the art of making dumbbells. In some embodiments, the overall weight or mass of dumbbell 10 can be a function of the weight or mass of handle 14, braces 19 and of each weight 22, which can further be a function of its thickness 26. In the illustrated embodiment of FIGS. 5A and 5B, thickness 26 of weight 22 can be selected such that the overall weight of dumbbell can be approximately 3 pounds. In some embodiments, dumbbell 10 can comprise opening 28 disposed into an end of handle 14 to provide means for placing and storing dumbbell 10 on a weight tree or stand. In some embodiments, opening 28 can be disposed on the end of handle 14 adjacent to where braces 19 extend therefrom although in other embodiments, opening 28 can be disposed into the other end of handle 14.

Referring to FIGS. 6A and 6B, a fourth embodiment of improved dumbbell 10 is shown. In this embodiment, improved dumbbell 10 can comprise a plurality of weights 22 extending from braces 19 operatively coupled to end 15 of handle 14. In some embodiments, handle 14 can comprise grip 17 disposed at least partially thereon or therearound to provide improved grip to dumbbell 10 as well known to those skilled in the art. In some embodiments, grip 17 can be comprised of neoprene, rubber or other elastomeric material well known to those skilled in the art to provide enhanced grip to dumbbell 10. In other embodiments, grip 17 can comprise knurling on handle 14 to provide enhanced grip thereto. In some embodiments, handle 14 can further comprise wrap 11 (as shown in FIGS. 2 and 3) disposed at least partially therearound. In the illustrated embodiment, dumbbell 10 can comprise three weights 22 wherein each weight 22 is disposed substantially equidistant apart from an adjacent weight 22 wherein each weight 22 is disposed rotate by angle phi apart from its adjacent weights 22. In the illustrated embodiment, angle phi can be substantially 120°. In some embodiments, one or more weights 22 can be curved in configuration to form arc 24 as shown in FIGS. 6A and 6B. In some embodiments, arc 24 can provide additional space between weights 22 and handle 14 for a person to place their hand therearound while keeping the overall size of dumbbell 10 smaller than conventional dumbbells. In some embodiments, this embodiment of dumbbell can be comprised of metal, non-metal material with metal disposed therein or other suitable materials well known to those skilled in the art of making dumbbells. In some embodiments, the overall weight or mass of dumbbell 10 can be a function of the weight or mass of handle 14, braces 19 and of each weight 22, which can further be a function of its thickness 26. In the illustrated embodiment of FIGS. 6A and 6B, thickness 26 of weight 22 can be thicker than thickness 26 of dumbbell 10 of FIGS. 5A and 5B such that the overall weight of dumbbell 10 can be approximately 10 pounds. In some embodiments, dumbbell 10 can comprise opening 28 disposed into an end of handle 14 to provide means for placing and storing dumbbell 10 on a weight tree or stand. In some embodiments, opening 28 can be disposed on the end of handle 14 adjacent to where braces 19 extend therefrom although in other embodiments, opening 28 can be disposed into the other end of handle 14.

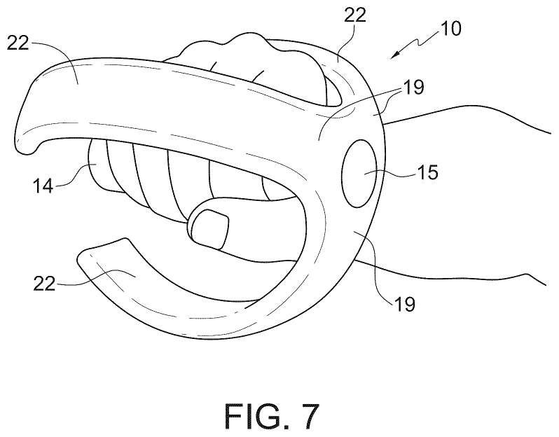

Referring to FIG. 7, the dumbbell of FIGS. 6A and 6B is shown in a position for exercise, wherein a person can grasp handle 14 by reaching through a pair of weights 22. When the person grasps two of dumbbells 10, one with each hand, the person can then engage in exercises by raising and lower their arms, extending and retracting their arms as well as moving their arms in a motion simulating boxing or other activity, all of which activity can result in strengthening the muscles and increasing the endurance of the person so exercising.

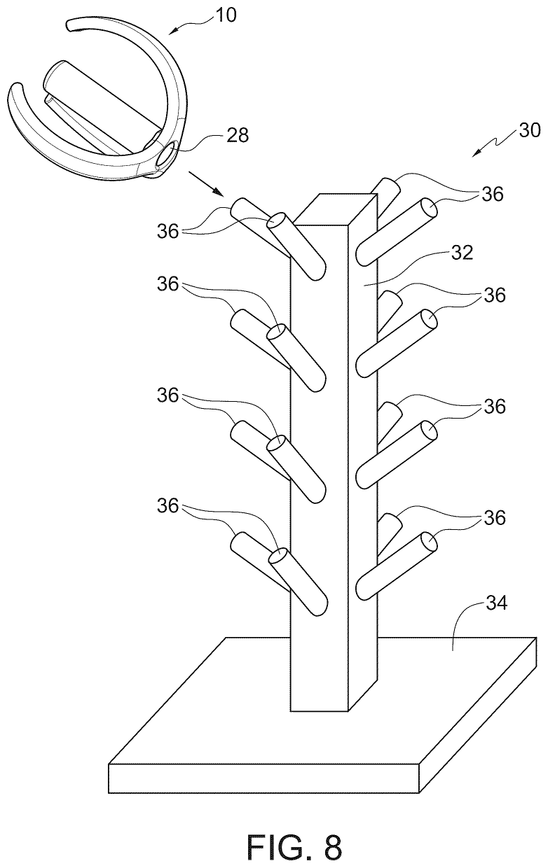

Referring to FIG. 8, one embodiment of weight stand 30 for use with dumbbell 10 is shown. In some embodiments, stand 30 can comprise of vertical post 32 extending upwards from base 34, wherein post 32 can comprise a plurality of pegs 36 extending therefrom for placing or storing dumbbell 10 thereon. In some embodiments, each peg 36 can be configured to fit within opening 28 disposed in dumbbell 10 as shown in FIGS. 5A and 6A as a means to place or store dumbbell 10 on a peg 36 on stand 30 when dumbbell 10 is not in use.

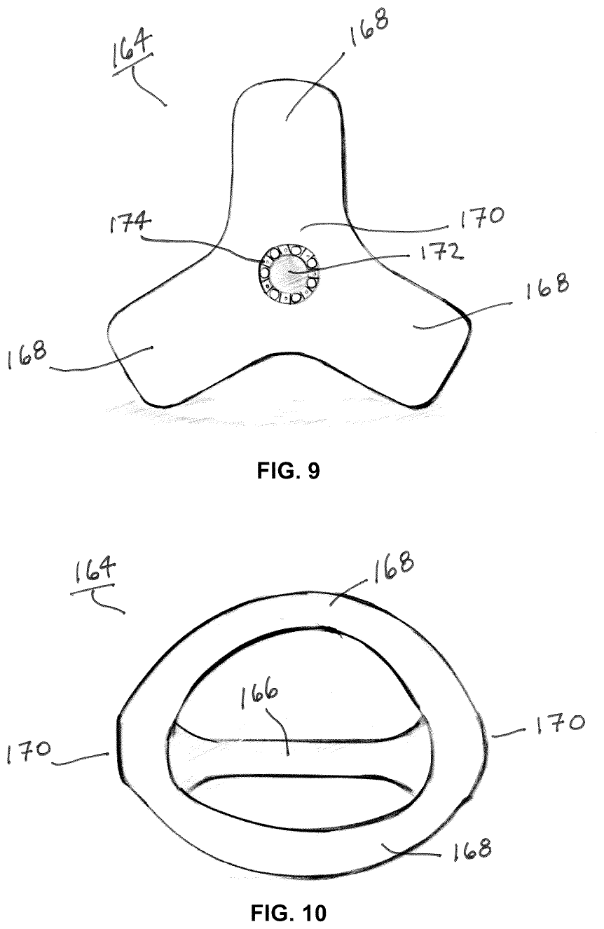

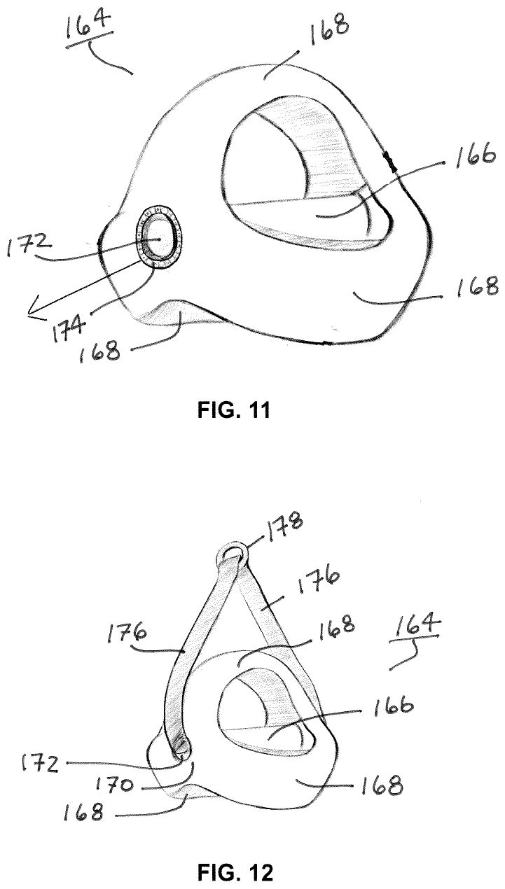

Referring to FIGS. 9, 10, and 11, one embodiment of dumbbell 164 is shown. Dumbbell 164, as presented herein, is an improvement of a dumbbell disclosed in Applicant's earlier patent publication no. US2021/0236873A1, which is incorporated by reference into this application in its entirety. In some embodiments, dumbbell 164 can comprise a plurality of curved weight segments 168 disposed between a pair of end faces 170. The physical dimensions and materials used in weight segments 168 can be selected to provide dumbbells 164 having various masses or weights. In some embodiments, dumbbell 164 can further comprise substantially straight handle segment 166 disposed between end faces 170 along longitudinal axis 167, wherein handle segment 166 in between the plurality of weight segments 168. In some embodiments, handle segment 166 can comprise of opening 172 extending therethrough. In some embodiments, handle segment 166 can be rotatably attached to dumbbell 164 via bearings 174 disposed on each end face 170.

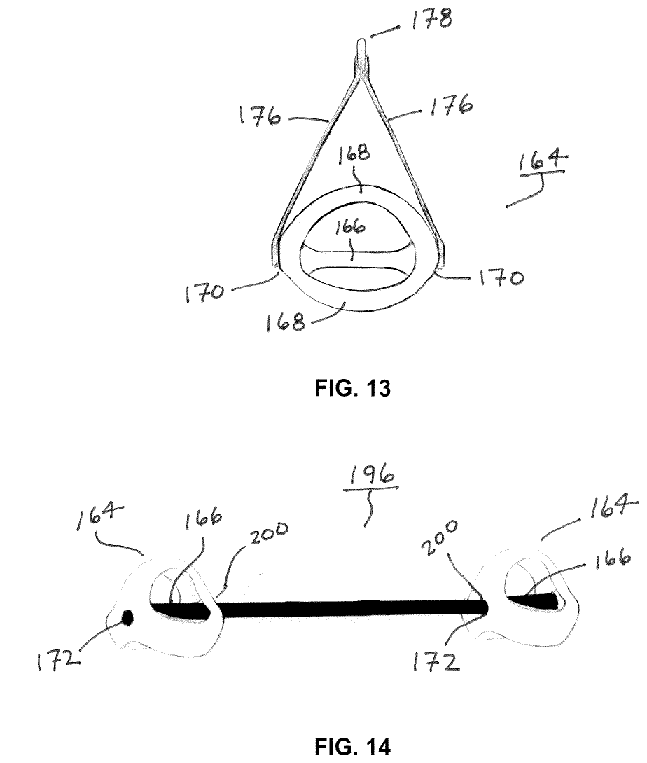

Referring to FIGS. 12 and 13, dumbbell 164 is shown having strap 176 placed through opening 172 to form a loop further comprising loop or ring 178 attached thereto so as to enable attaching ring 178 to weight resistance exercise machines, such as those using cables to pull on a weight stack as well known to those skilled in the art, so as to provide a weighted handle for use with such exercise machines.

Referring to FIG. 14, one embodiment of barbell 196 is shown using dumbbells 164 as weights on opposing ends of bar 198. In some embodiments, the ends of bar 198 can be inserted into openings 172 of dumbbells 164 and can be held in place by releasable attachment mechanism 200. In some embodiments, releasable attachment mechanism 200 can comprise one or more of threading means, spring-loaded catch devices, spring-loaded ball catch devices, and any other releasable attachment mechanisms as well known to those skilled in the art.

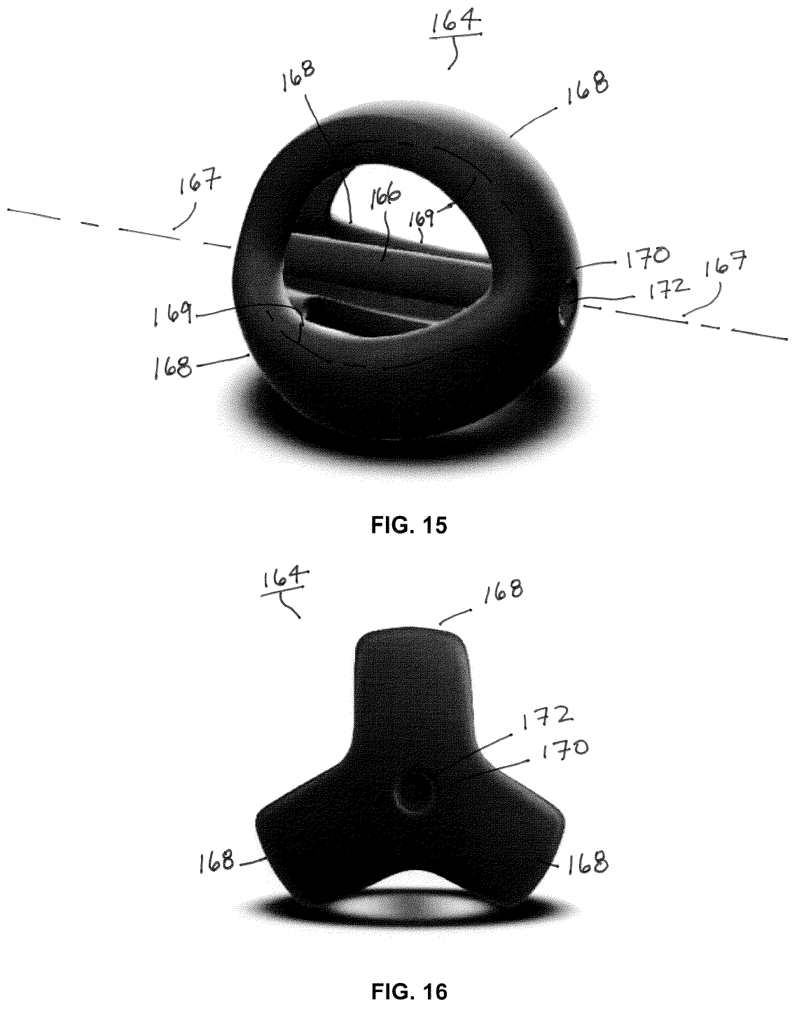

Referring to FIGS. 15, 16, and 17, one embodiment of dumbbell 164 is shown. In some embodiments, dumbbell 164 can comprise of handle 166 that can be substantially linearly straight along a longitudinal axis forming end faces 170 on both ends thereof. In some embodiments, dumbbell 164 can comprise one or more curved weight segments 168 following a curvilinear path between end faces 170. In the illustrated embodiment, dumbbell 164 is shown with three weight segments 168 spaced equidistant about handle 166 such that weight segments 168 are disposed approximately 120° apart from each other. The weight or mass of dumbbell 164 can be a function of the mass density of the material used to form dumbbell 164 and the cross-sectional dimensions of weight segments 168. In some embodiments, dumbbell 164 can be comprised metal, such as steel or cast iron. In other embodiments, dumbbell 164 can be comprised of rubber, such as high-density rubber as known to those skilled in the art. In further embodiments, dumbbell 164 can be comprised of metal, as noted above, covered in rubber or high-density rubber. In yet other embodiments, dumbbell 164 can be comprised of a shell of rubber or high-density plastic, such as high-density polyethylene (HDPE), or other functional equivalents as well known by those skilled in the art, that can be filled with metal beads, ball bearings, lead shot, sand or water, or other suitable media, as well known by those skilled in the art for producing exercise weight equipment, for producing a dumbbell of a desired mass or weight.

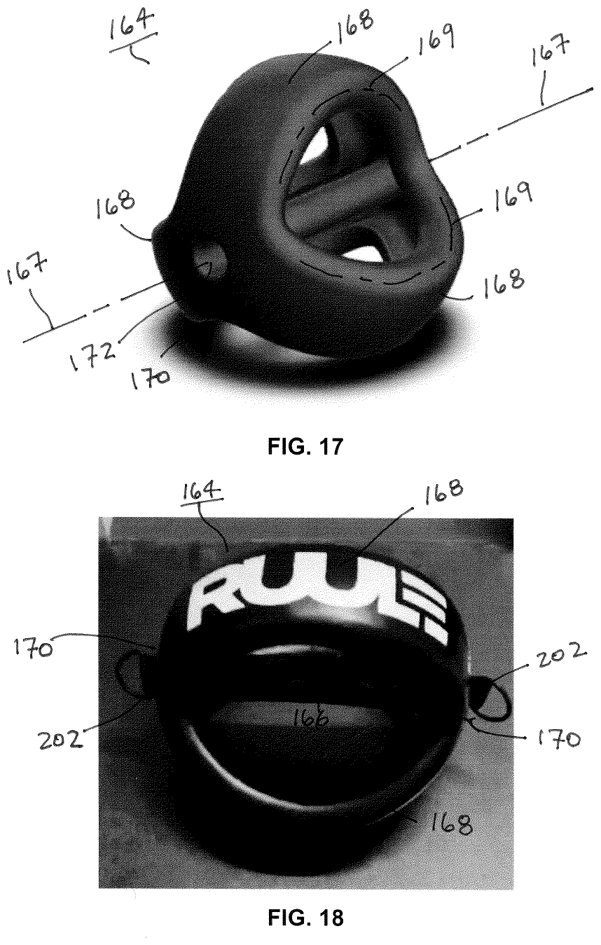

In some embodiments, one or more weight segments 168 can be curved in configuration to form arc 169 as shown in FIGS. 15 and 17. In some embodiments, arc 169 can provide additional space between weight segments 168 and handle 166 for a person to place their hand therearound while keeping the overall size of dumbbell 164 smaller than conventional dumbbells. In some embodiments, this embodiment of dumbbell can be comprised of metal, non-metal material with metal disposed therein or other suitable materials well known to those skilled in the art of making dumbbells. In some embodiments, the overall weight or mass of dumbbell 164 can be a function of the weight or mass of handle 166 and weight segments 168, which can further be a function of its thickness, its cross-sectional area and the mass density of the material used to form dumbbell 164.

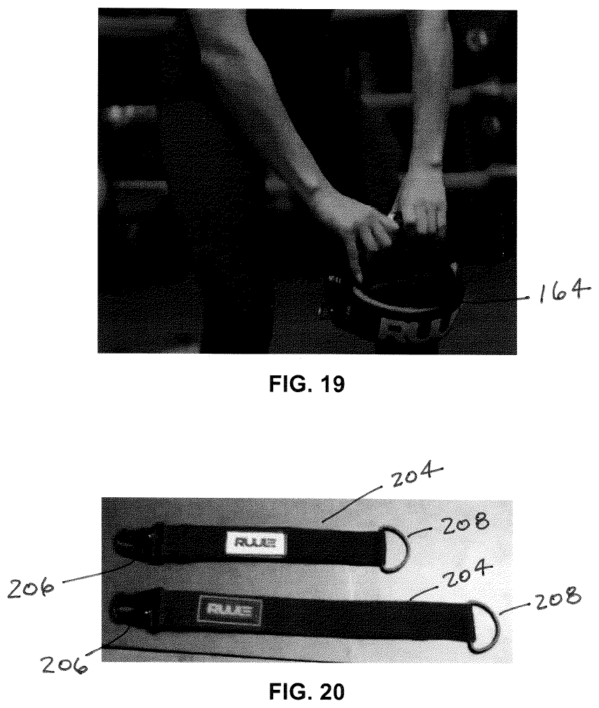

Referring to FIG. 18, another embodiment of dumbbell 164 is shown. In this illustrated embodiment, dumbbell 164 can comprise of loop or ring 202 disposed on one or both of end faces 170. Referring to FIG. 19, illustrated is a way of exercising with dumbbell 164 by lifting and moving dumbbell 164 similar to how one would exercise with a kettle bell as well known to those skilled in the art.

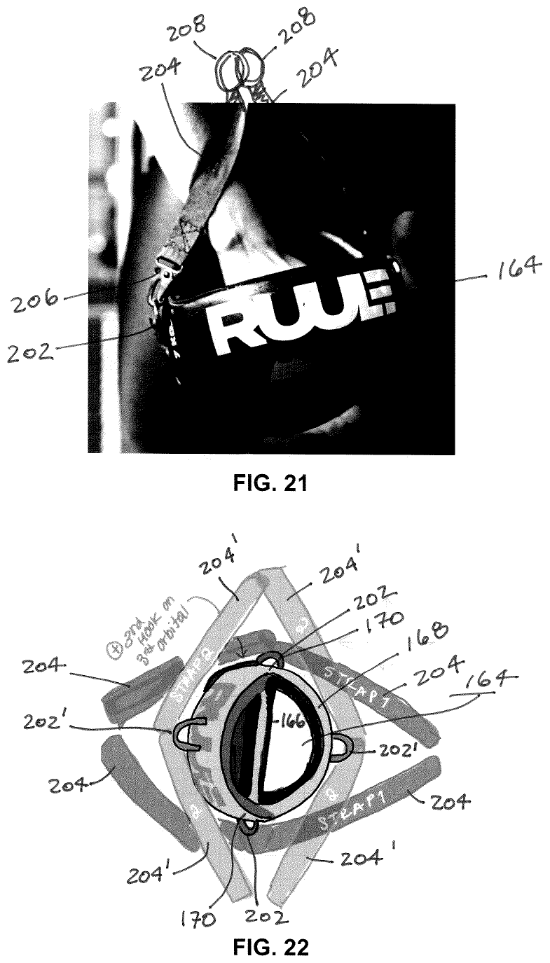

Referring to FIG. 20, embodiments of straps 204 for use with dumbbell 164 are shown, which can comprise of clip 206 disposed on one end thereof and loop or ring 208 on an opposing end thereof. In some embodiments, clip 206 attach to loop or ring 202 of dumbbell 164 wherein loop or ring 208 of strap 204 can attach to an exercise machine, as described in more detail below. Referring to FIG. 21, one embodiment of dumbbell 164 is shown with two straps 204 attached thereto for attachment to an exercise machine (not shown) such that dumbbell 164 can function as the handle coupled to the exercise machine wherein the additional weight or mass of dumbbell 164 provides additional resistance to enhance the effects of exercise on the exercise machine.

Referring to FIG. 22, another embodiment of dumbbell 164 is shown. In this embodiment, dumbbell 164 can comprise of loops or rings 202′ disposed on apex 169 of arc 169 on one or more of weight segments 168 in addition to loops or rings 202 disposed on end faces 170. In some embodiments, one or more straps 204 can be attached to one or more loops or rings 202 and/or one or more straps 204′ can be attached to one or more loops or rings 202′. Thus, in some embodiments, dumbbell 164 can be attached to an exercise machine in a variety of attachment orientations with the exercise machine such that dumbbell 164 can function as the handle coupled to the exercise machine wherein the additional weight or mass of dumbbell 164 provides additional resistance to enhance the effects of exercise on the exercise machines.

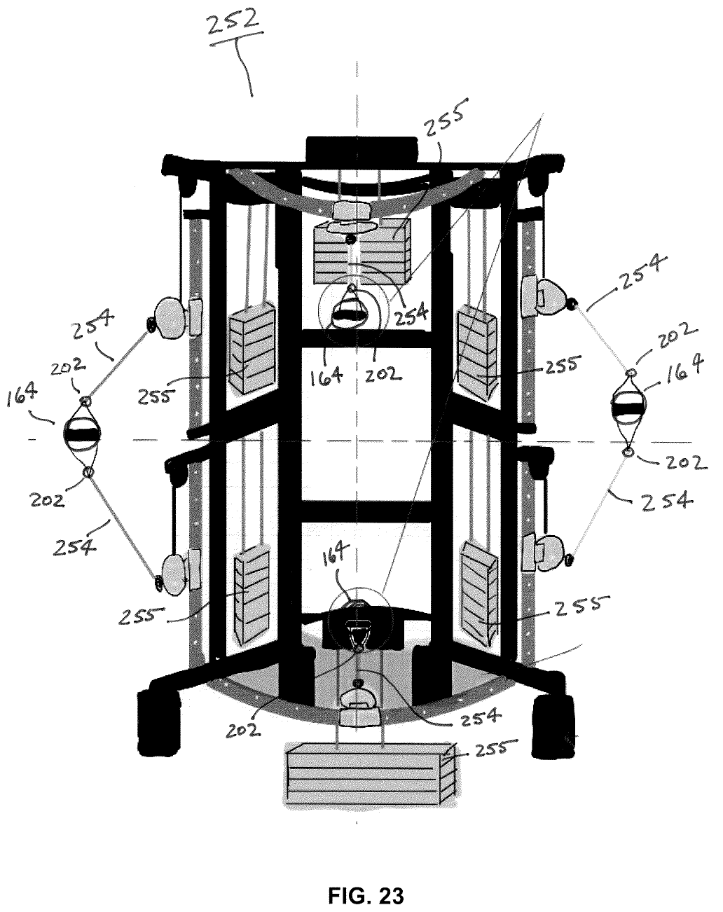

Referring to FIG. 23, one embodiment of cable exercise machine 252 for use with dumbbell 164 is shown. In some embodiments, cable exercise machine 252 can comprise of one or more cables 254 operatively coupled to weight stacks 255. In some embodiments, one or more of cables 254 can attach to one or more of dumbbell 164. In the illustrated embodiment, cables 254 can be attached to dumbbell 164 via loop or ring 202 disposed thereon. In some embodiments, one or more of dumbbell 164 can be attached to cables 254 wherein a person using dumbbell 164 can perform exercise movements in cable exercise machine 252 with the added resistance of the weight of dumbbell 164 in combination with weight stacks 255.

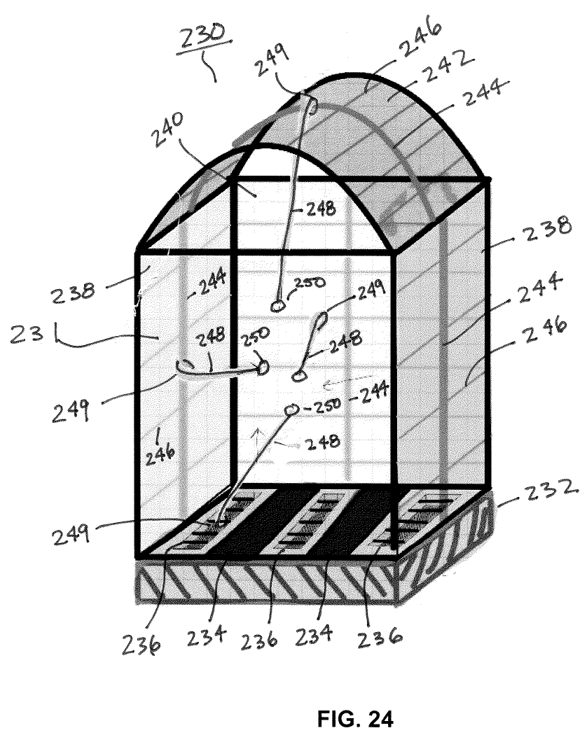

Referring to FIG. 24, one embodiment of cage 230 for use with dumbbell 164 is shown. In some embodiments, cage 230 can comprise of elevated base 232, sidewalls 238, rear wall 240, and roof 242 supported thereon to form opening 231 to allow a person to enter cage 230. In some embodiments, base 232 can comprise of one or more floor portions 234 and one or more grate portions 236 for attaching resistance band 248 thereto at attachment point 249. In some embodiments, one or more of sidewalls 238, rear wall 240, and roof 240 can comprise of first attachment members 244 disposed therein, and of one or more second attachment members 246 disposed therein wherein first and second attachment members are substantially orthogonal to each other. In some embodiments, one or both of first and second attachment members can be configured for attaching resistance bands 248 thereto at attachment points 249. In some embodiments, one or more of resistance bands 248 can comprise attachment loop or clip 250 disposed on the loose end thereof. In some embodiments, one or more of dumbbell 164 can be attached to resistance bands 248 via attachment loop or clip 250 wherein a person using dumbbell 164 can perform exercise movements in cage 230 with resistance bands 248 with the added resistance of the weight of dumbbell 164.

Although a few embodiments have been shown and described, it will be appreciated by those skilled in the art that various changes and modifications can be made to these embodiments without changing or departing from their scope, intent or functionality. The terms and expressions used in the preceding specification have been used herein as terms of description and not of limitation, and there is no intention in the use of such terms and expressions of excluding equivalents of the features shown and described or portions thereof, it being recognized that the invention is defined and limited only by the claims that follow.

We claim:

1. A dumbbell, comprising:
a) a substantially straight handle segment disposed along a longitudinal axis between a pair of end faces; and
b) a plurality of curved weight segments disposed along an arc path between the pair of end faces thereby enclosing the handle segment.

2. The dumbbell as set forth in claim 1, wherein the handle segment is rotatably attached thereto.

3. The dumbbell as set forth in claim 1, wherein the handle segment comprises an opening extending therethrough between the pair of end faces.

4. The dumbbell as set forth in claim 4, further comprising a strap disposed through the opening, the strap further comprising a ring for attachment to weight resistance exercise equipment.

5. The dumbbell as set forth in claim 1, further comprising a barbell having first and second ends, the first end disposed in the opening of the dumbbell, the second end disposed in the opening of another of the dumbbell.

6. The dumbbell as set forth in claim 1, further comprising an attachment mechanism disposed on one or both of the end faces, the attachment mechanism for attaching to weight resistance exercise equipment.

7. The dumbbell as set forth in claim 1, further comprising an attachment mechanism disposed on one of more of the curved weight segments, the attachment mechanism for attaching to weight resistance exercise equipment.

8. An improved dumbbell, comprising:
a) a first weight;
b) at least one first support member extending substantially from the first weight;
c) a substantially horizontal handle extending from a first end of the at least one first support member;
d) a plurality of sets of at least one second support member extending from the first end of the at least one first support member; and
e) a second weight disposed on furthermost ends of each of the at least one second support member.

9. The improved dumbbell as set forth in claim 8, wherein the first weight comprises a substantially flat bottom surface thereby the dumbbell is configured to stand unsupported without tipping over.

10. The improved dumbbell as set forth in claim 8, wherein the at least one first support member is substantially vertical extending upwardly from the first weight.

11. The improved dumbbell as set forth in claim 8, wherein the at least one second support member is rotated by an angle phi relative to the at least one first support member.

12. The improved dumbbell as set forth in claim 11, wherein the angle phi ranges from 90° to 160°.

13. The improved dumbbell as set forth in claim 8, wherein the second weight comprises less weight or mass than that of the first weight.

14. The improved dumbbell as set forth in claim 13, wherein the weight or mass of the second weight ranges from 0.1 to 1.0 of that of the first weight.

15. The improved dumbbell as set forth in claim 8, further comprising a proprioceptive wrap disposed at least partially around the handle.

16. An improved dumbbell, comprising:
a) a pair of base weights;
b) two sets of first support members, wherein each of the pair of base weights comprises one of the two sets of first support members extending substantially upwards therefrom;
c) a substantially horizontal handle extending between upper ends of the first support members;
d) two sets of second support members extending upwards from the upper ends of the first support members; and
e) an upper weight disposed on uppermost ends of each of the two sets of second support members.

17. The improved dumbbell as set forth in claim 16, wherein each of the pair of base weights comprises a substantially flat bottom surface thereby the dumbbell is configured to stand unsupported without tipping over.

18. The improved dumbbell as set forth in claim 16, wherein the two sets of first support members are separated by an angle alpha.

19. The improved dumbbell as set forth in claim 18, wherein the angle alpha ranges from 45° to 135°.

20. The improved dumbbell as set forth in claim 16, wherein the second support members are rotated by an angle phi relative to the first support members.

21. The improved dumbbell as set forth in claim 20, wherein the angle phi ranges from 45° to 135°.

22. The improved dumbbell as set forth in claim 16, wherein the upper weights comprise less weight or mass than that of the base weights.

23. The improved dumbbell set forth in claim 22, wherein the weight or mass of the upper weights range from 0.1 to 1.0 of that of the base weights.

24. The improved dumbbell as set forth in claim 16 further comprising a proprioceptive wrap disposed at least partially around the handle.
